(19) United States
(12) Patent Application Publication
(10) Pub. No.: US 2014/0287287 A1
(43) Pub. Date: Sep. 25, 2014

(54) BATTERY SYSTEM AND EVALUATION METHOD FOR BATTERY

(71) Applicant: WASEDA UNINVERSITY, Tokyo (JP)

(72) Inventors: Tetsuya Osaka, Shinjuku-ku (JP); Toshiyuki Momma, Shinjuku-ku (JP); Tokihiko Yokoshima, Shinjuku-ku (JP); Daikichi Mukoyama, Shinjuku-ku (JP); Hiroki Nara, Shinjuku-ku (JP)

(73) Assignee: WASEDA UNIVERSITY, Tokyo (JP)

(21) Appl. No.: 14/351,361

(22) PCT Filed: Oct. 10, 2012
(86) PCT No.: PCT/JP2012/076217

§ 371 Date: Apr. 11, 2014

(30) Foreign Application Priority Data
Oct. 13, 2011 (JP) 2011-226143

(51) Int. Cl. G01R 31/36; H01M 10/42

(52) U.S. Cl. CPC G01R 31/3641; G01R 31/3627; H01M 10/425
USPC 429/92; 324/430

(57) ABSTRACT

A battery system 1 includes a secondary battery 10 including a positive electrode 11, a negative electrode 15, and electrolytes 12 and 14, a storing section 23 configured to store peculiar information of the secondary battery 10 measured in advance including an initial resistance value and an evaluation frequency, a power supply section 20 configured to apply an alternating current signal having the evaluation frequency stored in the storing section 23 to the secondary battery 10, a measuring section 22 configured to measure impedance of a solid electrolyte interphase 17 of the secondary battery 10 from the alternating current signal, and a calculating section 24 configured to calculate at least one of a deterioration degree and a charging depth of the secondary battery 10 from the impedance and the peculiar information.

### TECHNICAL FIELD

Embodiments of the present invention relate to a battery system including a secondary battery and an evaluation method for a battery.

### BACKGROUND ART

Secondary batteries are used in a portable device, an electric tool, an electric automobile, and the like. Among the secondary batteries, a lithium ion battery has a high operating voltage and can easily obtain a high output and, in addition, has a high-energy density characteristic because ionization tendency of lithium is large. Further, applications to large power supplies such as a stationary power supply and an emergency power supply are also expected.

As a method of measuring characteristics of a secondary battery such as a lithium ion battery, an alternating-current impedance method is known. For example, Japanese Patent Application Laid-Open Publication No. 2009-97878 discloses a measuring method for analyzing, using an equivalent circuit model, a Cole-Cole plot of a battery acquired by an alternating-current impedance method.

On the other hand, Japanese Patent Application Laid-Open Publication No. 8-43507 discloses a method of simply estimating a deterioration state or a capacity of a measured battery by specifying a frequency having a high correlation with impedance and a battery capacity.

However, a characteristic mechanism of the secondary battery is complicated and there is a demand for a measuring method having higher accuracy, in particular, a measuring method supported by theory. Further, in order to perform accurate measurement with the alternating-current impedance method, a power supply capable of sweeping a frequency and a special analyzing apparatus are necessary. Therefore, it is not easy for a user to accurately learn, while using a battery, a deterioration degree or a charging depth of the battery.

It is an object of embodiments of the present invention to provide a battery system having a simple configuration that evaluates characteristics of a secondary battery and an evaluation method for a battery using a simple configuration.

### DISCLOSURE OF INVENTION

### Means for Solving the Problem

A battery system according to an embodiment of the present invention includes: a secondary battery including a positive electrode, a negative electrode, and an electrolyte; a storing section configured to store peculiar information including an initial resistance value and an evaluation frequency of one secondary battery having the same specification as the secondary battery; a power supply section configured to apply an alternating current signal having the evaluation frequency stored in the storing section to the secondary battery; a measuring section configured to measure impedance based on a solid electrolyte interphase according to the alternating current signal; and a calculating section configured to calculate at least one of a deterioration degree and a charging depth of the secondary battery from the impedance and the peculiar information.

An evaluation method for a battery according to another embodiment includes: a manufacturing step of manufacturing a plurality of secondary batteries; a step of performing a Cole-Cole plot analysis of one of the secondary batteries using an equivalent circuit model, which takes into account a positive electrode, a negative electrode, and a solid electrolyte interphase, and acquiring peculiar information including an initial resistance value and an evaluation frequency; a step of applying an alternating current signal having the evaluation frequency to the respective secondary batteries and measuring impedance based on the solid electrolyte interphase; and a step of calculating deterioration degrees or charging depths of the respective secondary batteries from the peculiar information and the impedance.

### BRIEF DESCRIPTION OF THE DRAWINGS

FIG. 1 is a configuration diagram for explaining a configuration of a battery system in a first embodiment;

FIG. 2 is a publicly-known equivalent circuit model for describing internal impedance of a lithium ion battery;

FIG. 3 is a diagram showing a fitting result to a Cole-Cole plot by the equivalent circuit model shown in FIG. 2;

FIG. 4 is an equivalent circuit model of a battery system in an embodiment for describing internal impedance of a lithium ion battery;

FIG. 5 is a diagram showing a fitting result to a Cole-Cole plot by the equivalent circuit model in the embodiment shown in FIG. 4;

FIG. 6 is a diagram showing an analysis result of the Cole-Cole plot by the equivalent circuit model in the embodiment shown in FIG. 4;

FIG. 7 is a diagram showing a cycle test result by an evaluation method for a battery in the embodiment;

FIG. 8 is a diagram showing the cycle test result by the evaluation method for the battery in the embodiment;

FIG. 9 is a diagram showing the cycle test result by the evaluation method for the battery in the embodiment;

FIG. 10 is a diagram showing the cycle test result by the evaluation method for the battery in the embodiment;

FIG. 11 is a flowchart showing a flow of processing of the evaluation method for the battery in the embodiment;

FIG. 12 is a configuration diagram for explaining a configuration of a battery system in a second embodiment; and

FIG. 13 is a diagram for explaining an effect of the battery system in the second embodiment.

### BEST MODE FOR CARRYING OUT THE INVENTION

### First Embodiment

### Configuration of Battery System

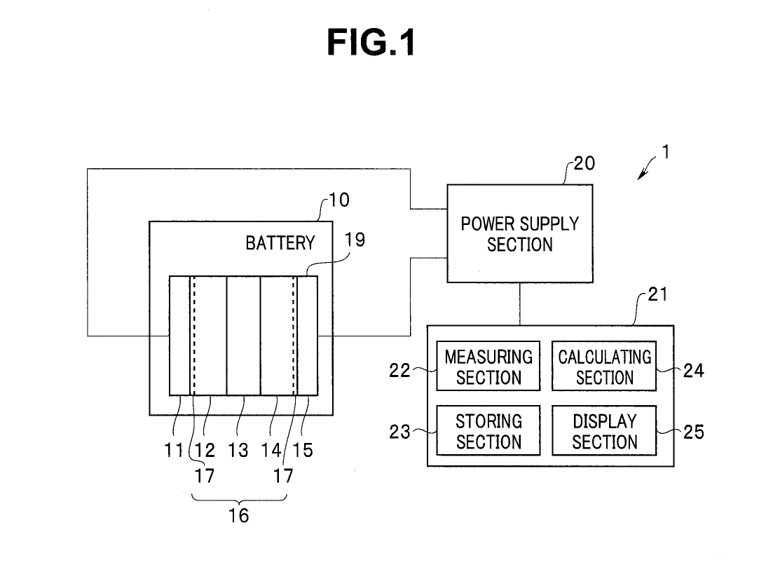

As shown in FIG. 1, a battery system 1 in a first embodiment includes a lithium ion secondary battery (hereinafter referred to as “battery”) 10, a power supply section 20, and a control section 21. The battery 10 includes a unit cell 19 including a positive electrode 11 for occluding/emitting lithium ions, electrolytes 12 and 14, a separator 13, and a negative electrode 15 for occluding/emitting lithium ions. Note that the battery 10 may include a plurality of the unit cells 19 or may include a plurality of units formed by a plurality unit cells.

The battery 10 is a lithium ion battery. The positive electrode 11 contains, for example, a lithium-cobalt oxide. The negative electrode 15 contains, for example, a carbon material. The separator 13 is formed of, for example, polyolefin. The electrolytes 12 and 14 are, for example, electrolytes obtained by dissolving LiPF6 in cyclic or chain carbonate. Note that the battery 10 may have a structure in which electrolytes are filled inside a separator formed of a porous material or the like. Therefore, in the following explanation, a structure obtained by combining the electrolytes 12 and 14 and the separator 13 is sometimes referred to as electrolyte 16. As explained below, a solid electrolyte interphase 17 is formed by a side reaction of a battery and allows lithium ions to pass but does not allow electrons to pass.

Note that the battery 10 shown in FIG. 1 is a schematic diagram. A structure of the unit cell 19 of the battery 10 may be publicly-known various structures, for example, a wound type cell, a coin type cell, or a laminate cell. Further, materials of the positive electrode 11, the negative electrode 15, the separator 13, and the like are not limited to the materials described above. Publicly-known various materials can be used.

The control section 21 includes a storing section 23, a measuring section 22, a calculating section 24, and a display section 25. As explained below, the storing section 23 stores peculiar information of a battery having the same specifications as the battery 10 measured in advance including an initial resistance value and an evaluation frequency. That is, the storing sections 23 of a plurality of the batteries 10 having the same specifications store the same peculiar information at the time of shipment. The power supply section 20 applies an alternating current signal having the evaluation frequency stored in the storing section 23 to the battery 10. The measuring section 22 measures impedance of the battery 10 from the alternating current signal applied to the battery 10 by the power supply section 20. The calculating section 24 calculates at least one of a deterioration degree and a charging depth of the battery 10 from the impedance and the peculiar information of the battery 10.

The display section 25 displays a calculation result of the calculating section 24 in a form that a user can recognize. Note that, for example, when the battery system 1 is used as a part of another system, if the user can recognize the calculation result using a display function or the like of the other system, the display section 25 is unnecessary.

### Operation of Battery System

An alternating-current impedance method for a battery is explained. In the alternating-current impedance method, a voltage obtained by superimposing a very small alternating-current voltage on a direct-current voltage is applied to the battery. Impedance is measured from a response characteristic. In the alternating-current impedance measuring method, since an applied alternating-current voltage is small, it is possible to measure an impedance characteristic without changing a state of a measurement target secondary battery.

A direct-current voltage component is set to a degree of a voltage of a battery to be measured. An alternating-current voltage component to be superimposed on the direct-current voltage component is set to a voltage of a degree not affecting characteristics of the battery. As the alternating-current voltage component to be superimposed, an alternating current set to the voltage of the degree not affecting the characteristics of the battery may be used.

In the alternating-current impedance measurement method, a frequency of an alternating-current voltage is swept from a high frequency to a low frequency. Impedances of a battery at respective frequencies are measured at a predetermined frequency interval.

Note that, in the following explanation, alternating-current impedance measurement for creating a Cole-Cole plot was performed under conditions described below.
Frequency measurement range: 1 MHz to 1 mHz
Voltage amplitude: 5 mV
Temperature: 25° C.

A frequency characteristic of measured impedance can be represented on a complex plane diagram in which a real number axis indicates a resistance component and an imaginary number axis indicates a reactance component (usually, capacitative). When a measurement frequency is changed from a high frequency to a low frequency, a Cole-Cole plot, which is a track of impedance including a semicircle clockwise, is obtained.

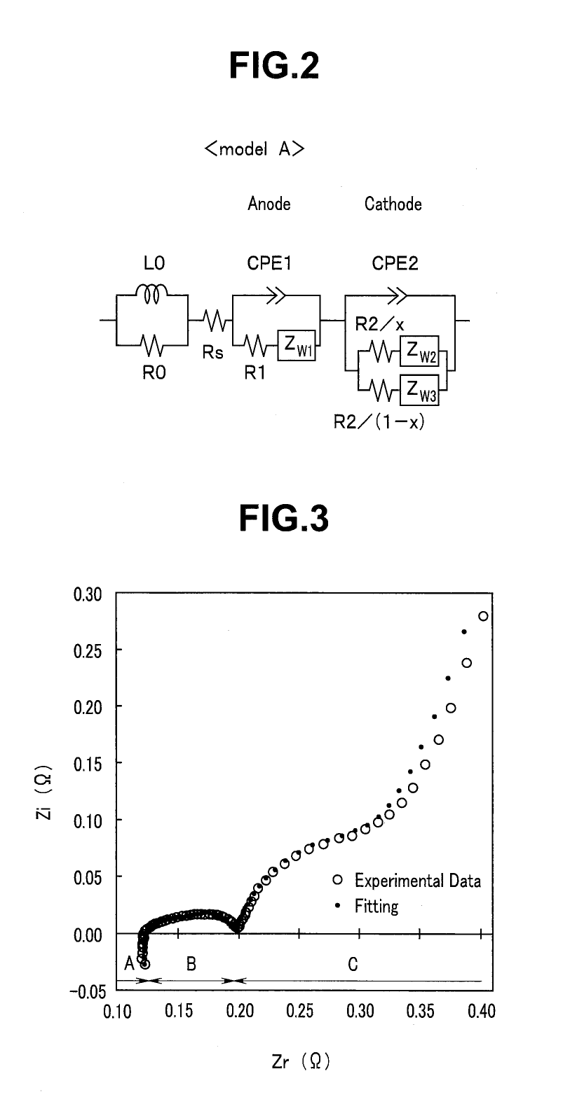

In order to theoretically analyze characteristics of the battery on the basis of the Cole-Cole plot, fitting processing based on an equivalent circuit model is performed. A general equivalent circuit model A shown in FIG. 2 is configured by a circuit 31 corresponding to a structure of the battery, a circuit 32 corresponding to the positive electrode 11, and a circuit 33 corresponding to the negative electrode 15.

That is, electrodes (a positive electrode and a negative electrode) opposed to each other are present in the battery. Electrochemical reactions proceed in the respective electrodes. An inductance component is likely to be present between a reaction field and an impedance measuring system. In addition, in the equivalent circuit model A, a particle diameter distribution of active material particles in an electrode bonding agent is taken into account from knowledge in the past. It is possible to perform an analysis having relatively high accuracy.

That is, the equivalent circuit model A shown in FIG. 2 includes the circuit 31 (an inductor L0 and a resistor R0), a solution resistor Rs, the circuit 32 (a capacitor CPE1, a resistor R1, and a diffused resistor Zw1), the circuit 33 (a capacitor CPE2, a resistor R2/x, a resistor R2(1−x), and diffused resistors ZW2 and ZW3).

An equivalent circuit model and initial values of respective parameters are inputted to a simulator. Fitting processing is performed to repeatedly perform calculation while adjusting the respective parameters such that a Cole-Cole plot obtained by calculation coincides with measurement data.

In the equivalent circuit model A shown in FIG. 2, since the two electrodes, i.e., the positive electrode 11 and the negative electrode 15 are present, the Cole-Cole plot draws a track of overlapping two semicircles.

In FIG. 3, a fitting result to the Cole-Cole plot obtained by using the equivalent circuit model A is shown. That is, by using the equivalent circuit model A, it is seen that a relatively satisfactory fitting result is obtained in an inductance region (a region A) and a charge transfer reaction region (a region B). However, a fitting result is not considered satisfactory in an ion diffusion region (a region C). When examined carefully, a sufficient result is not considered to be obtained in the region B either.

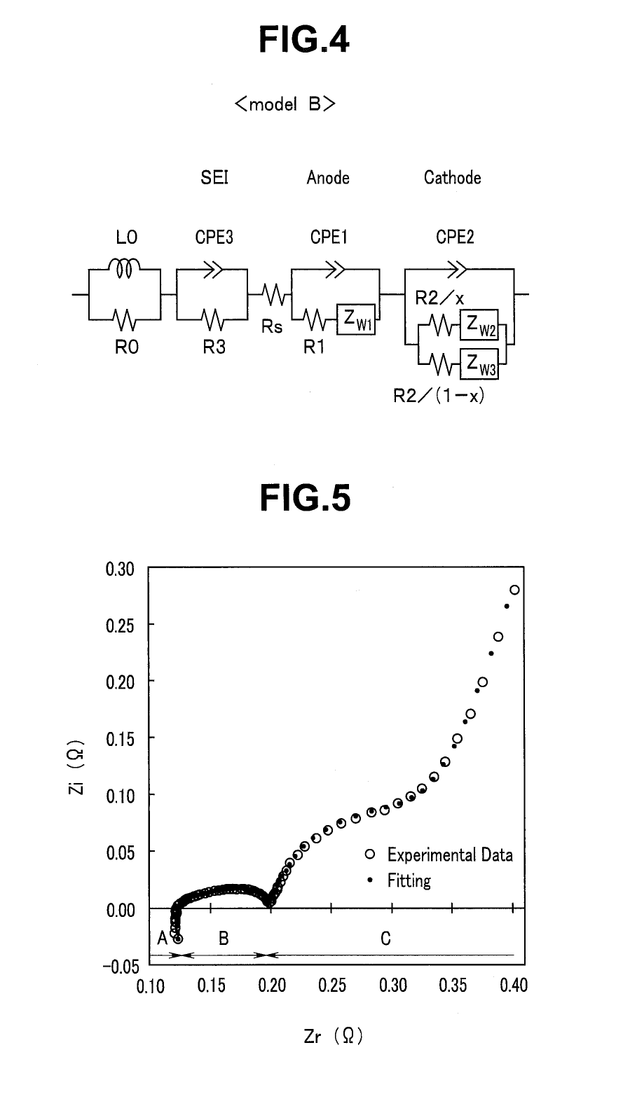

To cope with this problem, the inventor devised an equivalent circuit model B closer to an electrochemical configuration of a battery and attempted fitting to a Cole-Cole plot. FIG. 4 is an equivalent circuit model B that takes into account a solid electrolyte interphase (hereinafter referred to as “SEI”). That is, in the equivalent circuit model B, the circuit 33 (the capacitor CPE3 and the resistor R3), which takes into account the SEI, is added to the equivalent circuit model A.

The solid electrolyte interphase (SEI) is a film formed on an electrode surface by a side reaction of the lithium ion secondary battery 10. That is, the SEI is foamed to cover the electrodes by a decomposition reaction of an electrolyte/an electrolytic solution and a reaction of the electrolyte/the electrolytic solution and lithium ions. The SEI has electrical conductivity but does not have electron conductivity with respect to the lithium ions. Since the SEI has an effect of preventing the electrodes and the electrolyte from excessively reacting with each other, the SEI has a significant influence on a battery life.

In FIG. 5, a fitting result to a Cole-Cole plot obtained using the equivalent circuit model B is shown. That is, by using the equivalent circuit model B, a satisfactory fitting result was used in the ion diffusion region (the region C) as well. Further, a more satisfactory result was obtained in the inductance region (the region A) and the charge transfer reaction region (the region B) as well.

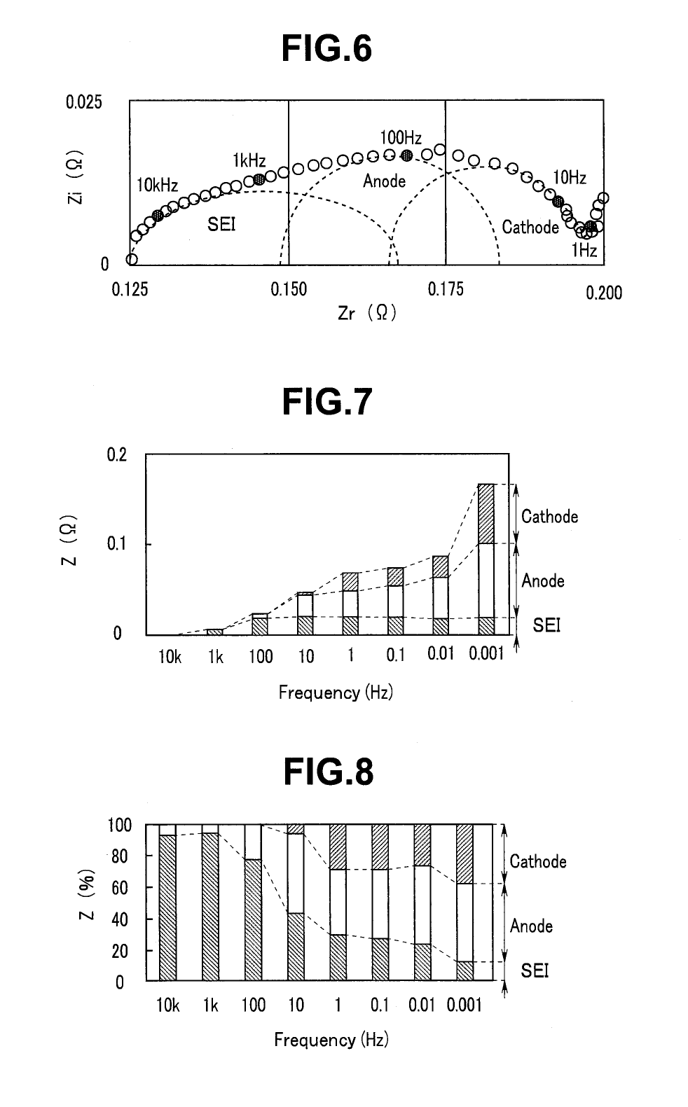

The SEI, which is an important component of the battery, was a part of the positive electrode and the negative electrode in the equivalent circuit model A. Therefore, the Cole-Cole plot was analyzed as a track of overlapping two semicircles in the region B. On the other hand, as shown in FIG. 6, in an analysis performed using the equivalent circuit model B, a track was decomposed into three semicircles. In the three semicircles, judging from time constants, charge transfer reactions to a charging state, and parameter changes concerning ion diffusion of the respective semicircles, a low-frequency side indicated a positive electrode component, a center indicated a negative electrode component, and a high-frequency side indicated an SEI component.

In FIG. 7 and FIG. 8, frequency dependency of impedance by the positive electrode, the negative electrode, and the SEI is shown. An absolute value of the impedance is larger as a frequency is lower. On the other hand, the impedance based on the SEI is larger as a frequency is higher. At 100 Hz or higher, in particular, at 500 Hz or higher, the impedance could be regarded as being based on only the SEI or could be easily separated into a component based on only the SEI.

In the analysis performed using the equivalent circuit model B, the impedance based on only the SEI can be acquired from the impedance by the positive electrode, the negative electrode, and the SEI, so-called combined impedance. Therefore, it is expected that the analysis greatly contributes to improvement of characteristics of the battery.

For example, the impedance by the positive electrode, the negative electrode, and the SEI due to a difference in a deterioration degree of the battery was measured.

In order to change the deterioration degree of the battery, a cycle test was performed. Impedances were measured in an initial period and at 100 cycles, 300 cycles, and 550 cycles and a Cole-Cole plot analysis was performed. In the cycle test, one cycle was set as from charging a voltage equivalent to 100% of an initial capacity to discharging the voltage to 0% of the initial capacity.

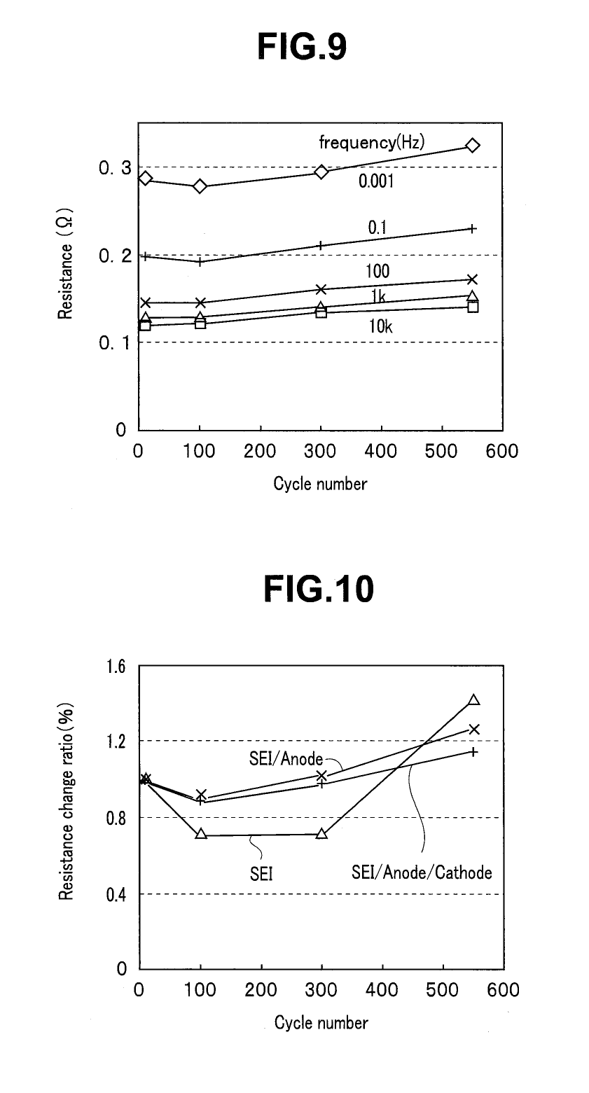

As shown in FIG. 9, a change in an absolute value of the combined impedance due to an increase in a cycle number, that is, deterioration of the battery is larger on a low-frequency side than on a high-frequency side. However, as shown in FIG. 10, a change ratio is large on the high-frequency side. As explained above, impedance R (SEI) based on only the SEI is shown at 100 Hz or higher, in particular, 500 Hz or higher on the high-frequency side. Note that, at 10 kHz or higher, impedance based on the electrolyte is predominant

That is, it was found that the impedance R (SEI) based on only the SEI obtained at an evaluation frequency equal to or higher than 500 Hz and lower than 10 kHz is suitable for calculating a deterioration degree of the battery.

If an initial resistance value (a nominal battery capacity) of the battery is known, a charging depth indicating a charged capacity with respect to a maximum capacity of the battery during measurement can also be calculated from the impedance R (SEI) based on the SEI. For example, the charging depth can be calculated by being extrapolated, at a current value of a ⅕ rate of the nominal battery capacity, from time in which a battery voltage during measurement changes to a rated voltage of the battery (a voltage at the time of a battery capacity 50%).

Note that, in FIG. 10, the impedance R (SEI) falls after 100 cycles. This is considered to be because, since a crack or the like occurs in a film generated on an interface, thickness of the SEI with respect to a surface area decreases.

As explained above, in the analysis performed using the equivalent circuit model B, it is possible to separate and grasp characteristic changes of the positive electrode, the negative electrode, and the SEI due to the deterioration of the battery. Therefore, when it is found that deterioration of any one of the positive electrode, the negative electrode, and the SEI is a cause of the deterioration of the battery, it is possible to reproduce the battery by replacing only the deteriorated component. That is, since the components not deteriorated can be reused, resource saving is possible.

Naturally, it is evident that it is beneficial to separate and grasp characteristic changes of the positive electrode, the negative electrode, and the SEI in a development stage of the battery as well.

In order to perform an analysis by a Cole-Cole plot, an evaluation system is necessary in which a power supply capable of sweeping a frequency is used. The analysis is not easy.

Therefore, the inventor performed the analysis by the Cole-Cole plot concerning only at least one battery during production of a battery system if batteries had the same specifications, devised an idea of calculating deterioration degrees and the like of the respective batteries with a simple configuration and a simple method after shipment of the battery system by using obtained peculiar information of the battery, and completed the battery system 1.

The peculiar information of the battery 10 includes an initial resistance value and an evaluation frequency. The evaluation frequency is a frequency of an alternating current signal and is, for example, a frequency equal to or higher than 500 Hz and lower than 10 kHz for measuring the impedance R (SEI) based on the SEI.

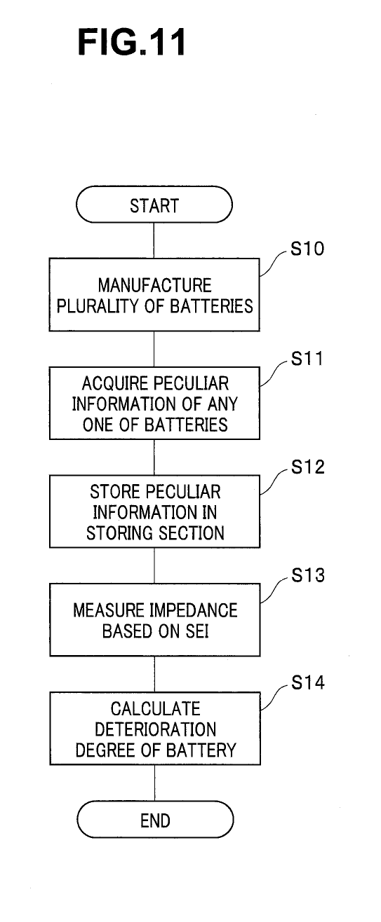

An evaluation method for the battery 10 is explained using a flowchart shown in FIG. 11.

### Step S10

The battery system 1 including the battery 10 having predetermined specifications is mass-produced. Note that, in this stage, peculiar information is not stored in the storing section 23.

### Step S11

At least one battery is selected out of a mass-produced plurality of batteries. It is preferable that a plurality of the batteries are selected depending on the number of produced batteries. When fluctuation during the production is taken into account, it is particularly preferable to select the batteries respectively from an initial lot and a final lot.

A Cole-Cole plot analysis of the selected battery is performed using the equivalent circuit model B that takes into account the positive electrode, the negative electrode, and the SEI. Peculiar information including an evaluation frequency for evaluating the impedance R (SEI) based on the initial resistance value and the SEI is acquired. The evaluation frequency is different depending on specifications of the battery. However, if the evaluation frequency is a frequency indicating capacitative reactance equal to or higher than 100 Hz or, preferably, equal to or higher than 500 Hz, it is possible to measure the evaluation frequency relatively less affected by charge transfer and diffusion in the positive electrode/the negative electrode. An upper limit of the evaluation frequency is, for example, lower than 10 kHz at which resistance of an electrolyte (an electrolytic solution) is predominant.

### Step S12

The peculiar information is stored in the storing sections 23 of the respective battery systems 1. The battery systems 1 are shipped. That is, the process to this step is a process during manufacturing.

### Step S13

After the shipment, when at least one of a deterioration degree and a charging depth of the battery 10 is measured, an alternating current signal having the evaluation frequency stored in the storing section 23 of the battery system 1 is applied by the power supply section 20. Impedance of the alternating current signal is measured by the measuring section 22.

### Step S14

At least one of the deterioration degree and the charging depth of the battery 10 is calculated from the peculiar information and the measured impedance by the calculating section 24.

A result calculated by the calculating section is recognized by the display section 25.

As explained above, the evaluation method for the battery by the battery system 1 is a measurement method having a simple configuration but having high accuracy and is, in particular, a measurement method supported by theory.

Further, as a modification of the battery system 1, it is also possible to simply calculate a deterioration degree of each of the positive electrode 11, the negative electrode 15, and the SEI (17). In order to learn the deterioration degree and the like of each of the positive electrode 11, the negative electrode 15, and the SEI (17), it is unnecessary to perform frequency sweeping for each of batteries and perform an analysis of a Cole-Cole plot of the battery. Impedance of a specific frequency indicating a state of each of the batteries only has to be measured.

That is, a characteristic change of the solid electrolyte interphase can be calculated by subtracting a value of a frequency equal to or higher than 10 kHz substantially equal to resistance of only the electrolyte 16 from impedance of an alternating current signal having a first frequency (evaluation frequency) fA equal to or higher than 500 Hz and lower than 10 kHz explained above, for example, 1 kHz. A characteristic change of negative electrode/SEI (17) combined resistance can be calculated by subtracting the resistance of the electrolyte 16 from impedance of an alternating current signal having a second frequency fB. A characteristic change of positive electrode/negative electrode 15/SEI (17) combined resistance can be calculated by subtracting the resistance of the electrolyte 16 from impedance of an alternating current signal having a third frequency fC.

It is possible to measure a resistance value change of a battery component involved in progress of deterioration simply by measuring the electrolyte resistance (10 kHz), the SEI resistance (1 kHz), the negative electrode/SEI combined resistance (100 Hz), and the positive electrode 11/negative electrode 15/SEI combined resistance (1 Hz). Therefore, a power supply capable of sweeping a frequency is unnecessary. It is possible to measure the resistance change value using a power supply including a relatively inexpensive frequency conversion circuit.

That is, in the battery system in the modification, the power supply section 20 can apply an alternating current signal having the first frequency fA, which is the evaluation frequency stored in the storing section 23, an alternating current signal having the second frequency ten times as high as the first frequency fA, and an alternating current signal having the third frequency fC ten times as high as the second frequency fB to the battery 10. The calculating section 24 can calculate a characteristic change of the solid electrolyte interphase 17 from impedance of the alternating current signal having the first frequency, calculate a characteristic change of the negative electrode 15 from impedance of the alternating current signal having the second frequency, and calculate a characteristic change of the positive electrode 11 from impedance of the alternating current signal having the third frequency.

Note that, as explained above, the first frequency, the second frequency, and the third frequency are in a relation of multiplication of predetermined proportionality coefficients. For example, in the example explained above, the relation is the first frequency fA: the second frequency fB: the third frequency fC=1:10:100. That is, the proportionality coefficients based on the first frequency are 10 and 100.

Therefore, it is possible to acquire any one of the frequencies, for example, the first frequency and calculate the other frequencies using the predetermined proportionality coefficients on the basis of the frequency. In other words, the first frequency and the proportionality coefficients may be stored in the storing section as peculiar information. Note that the proportionality coefficients are substantially fixed even if an initial capacity (a capacity at a start of use) of the battery changes. For example, the proportionality coefficients are substantially fixed in a low-capacity battery having a nominal capacity (an initial capacity) of 0.83 Ah and a large-capacity battery having a nominal capacity (an initial capacity) of 3.6 Ah. That is, the proportionality coefficients do not depend on a capacity (an output) of the battery.

### Second Embodiment

A battery system 1A in a second embodiment is explained. Since the battery system 1A is similar to the battery system 1, the same components are denoted by the same reference numerals and signs and explanation of the components is omitted.

As shown in FIG. 11, the battery system 1A includes a cooling section 60 configured to cool a temperature of the battery 10 and a temperature measuring section 70. The battery system 1A performs impedance measurement of the battery 10 in a cooled state. A cooling temperature is preferably equal to or lower than 0° C. and particularly preferably equal to or lower than −20° C. A lower limit of the cooling temperature is not particularly specified. However, the lower limit is, for example, −30° C., which is a lower limit in battery specifications.

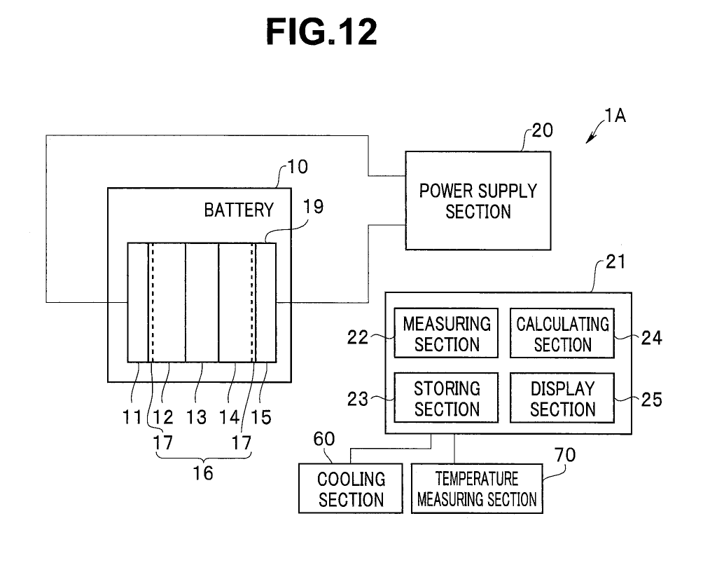

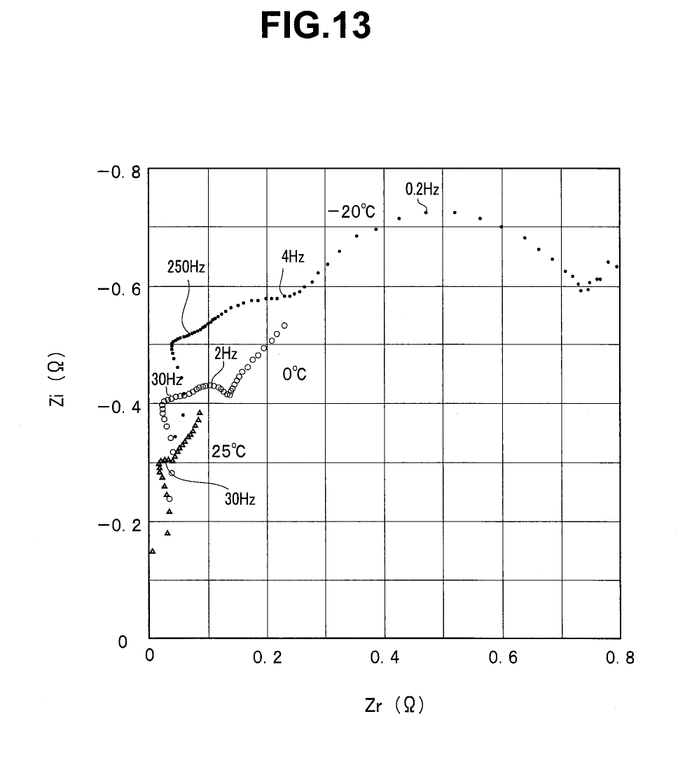

In FIG. 12, impedance measurement results (Cole-Cole plots) of the battery 10 not used yet at 25° C., 0° C., and −20° C. are shown. The battery 10 not used yet, that is, at a start of use has small SEI resistance compared with a battery used and deteriorated. Therefore, as shown in FIG. 12, a semicircle having a vertex at 30 Hz was observed at 25° C., two semicircles having vertexes at 30 Hz and 2 Hz were observed at 0° C., and three semicircles having vertexes at 250 Hz, 4 Hz, and 0.2 Hz were observed at −20° C.

As explained above, the semicircle of the Cole-Cole plot indicates a positive electrode component on a low-frequency side, a negative electrode component in a center, and an SEI component on a high-frequency side. Note that, even if the semicircle is apparently one semicircle as at a normal temperature (25° C.), the semicircle can be separated into respective components of a positive electrode/a negative electrode/an SEI by an analysis.

However, the results shown in FIG. 12 indicate that the respective components can be more easily separated at a low temperature than the normal temperature (25° C.). This is considered to be because respective charge transport reactions and active energies are different among the positive electrode, the negative electrode, and the SEI.

That is, the respective components can be easily separated when the temperature of the battery 10 is low, it is possible to extract a more highly accurate SEI component from the Cole-Cole plot.

The results shown in FIG. 12 indicate that an evaluation frequency for acquiring impedance based on the SEI changes according to the temperature. That is, in order to obtain a more highly accurate result, a calculating section needs information concerning temperature dependency.

Therefore, the battery system 1A stores information concerning temperature dependency in a storing section as peculiar information in advance. The calculating section performs correction processing using the temperature dependency information. Further, by cooling the battery 10 with the cooling section 60, it is possible to calculate a more highly accurate deterioration degree or charging depth.

Note that, for example, when the battery system 1 is used as a part of another system, if the other system has a temperature measuring function for measuring the temperature near the battery 10, the temperature measuring section 70 is sometimes unnecessary.

The battery system 1A and an evaluation method by the battery system 1A have effects same as the effects of the battery system 1 and the evaluation method by the battery system 1 and have high measurement accuracy.

The present invention is not limited to the embodiments explained above. Various modifications and alterations, for example, combinations of the components in the embodiments are possible in a range in which the gist of the present invention is not changed.

This application is based upon and claims priority from Japanese Patent Application No. 2011-226143 filed on Oct. 13, 2011 in Japan, the contents of which disclosed above are cited in this specification, claims, and the drawings.

1. A battery system comprising:
a secondary battery including a positive electrode, a negative electrode, and an electrolyte;
a storing section configured to store peculiar information including an initial resistance value and an evaluation frequency of one secondary battery having a same specification as the secondary battery;
a power supply section configured to apply an alternating current signal having the evaluation frequency stored in the storing section to the secondary battery;
a measuring section configured to measure impedance based on a solid electrolyte interphase according to the alternating current signal; and
a calculating section configured to calculate at least one of a deterioration degree and a charging depth of the secondary battery from the impedance and the peculiar information.

2. The battery system according to claim 1, wherein the evaluation frequency is equal to or higher than 100 Hz and lower than 10 kHz.

3. The battery system according to claim 2, wherein the battery system performs a Cole-Cole plot analysis of the one secondary battery using an equivalent circuit model, which takes into account the positive electrode, the negative electrode, and the solid electrolyte interphase, and acquires the peculiar information.

4. The battery system according to claim 3, further comprising:
a cooling section configured to cool a temperature of the secondary battery; and
a temperature measuring section configured to measure the temperature of the secondary battery.

5. The battery system according to claim 4, wherein the battery system measures the impedance of the secondary battery cooled to a temperature equal to or lower than 0° C. by the cooling section.

6. The battery system according to claim 5, wherein
the power supply section applies an alternating current signal having a first frequency, which is the evaluation frequency stored in the storing section, an alternating current signal having a second frequency, and an alternating current signal having a third frequency to the secondary battery, and
the calculating section calculates a characteristic change of the solid electrolyte interphase from impedance of the alternating current signal having the first frequency, calculates a characteristic change of the negative electrode from impedance of the alternating current signal having the second frequency, and calculates a characteristic change of the positive electrode from impedance of the alternating current signal having the third frequency.

7. The battery system according to claim 6, wherein the second frequency and the third frequency are calculated on the basis of a frequency of the first frequency using a predetermined proportionality coefficient stored in the storing section.

8. The battery system according to claim 7, wherein the predetermined proportionality coefficient does not depend on a capacity of the secondary battery.

9. An evaluation method for a battery comprising:
a manufacturing step of manufacturing a plurality of secondary batteries;
a step of performing a Cole-Cole plot analysis of one of the secondary batteries using an equivalent circuit model, which takes into account a positive electrode, a negative electrode, and a solid electrolyte interphase, and acquiring peculiar information including an initial resistance value and an evaluation frequency;
a step of storing the peculiar information in storing sections of the respective secondary batteries;
a step of applying an alternating current signal having the evaluation frequency to the respective secondary batteries and measuring impedance based on the solid electrolyte interphase; and
a step of calculating deterioration degrees or charging depths of the respective secondary batteries from the peculiar information and the impedance.

10. The evaluation method according to claim 9, wherein the evaluation frequency is equal to or higher than 100 Hz and lower than 10 kHz.

11. The evaluation method for the battery according to claim 10, wherein the impedance is measured at a temperature equal to or lower than 0° C.

12. The evaluation method for the battery according to claim 11, wherein
an alternating current signal having a first frequency, which is the evaluation frequency, an alternating current signal having a second frequency, and an alternating current signal having a third frequency are applied to the secondary battery, and
a characteristic change of the solid electrolyte interphase is calculated from impedance of the alternating current signal having the first frequency, a characteristic change of the negative electrode is calculated from impedance of the alternating current signal having the second frequency, and a characteristic change of the positive electrode is calculated from impedance of the alternating current signal having the third frequency.

13. The evaluation method for the battery according to claim 12, wherein any one of the first frequency, the second frequency, and the third frequency is acquired, and the other frequencies are calculated on the basis of the frequency using a predetermined proportionality coefficient.

14. The evaluation method for the battery according to claim 13, wherein the predetermined proportionality coefficient does not depend on a capacity of the secondary battery.
